(19) United States
(12) Patent Application Publication
(10) Pub. No.: US 2015/0247763 A1
(43) Pub. Date: Sep. 3, 2015

(54) OVERHEATING INDICATOR SYSTEM FOR POWER SUPPLY

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: QIANG LI, Wuhan (CN); YI-LIANG LI, Wuhan (CN); ZHI-GENG ZHANG, Wuhan (CN); YU-LIN LIU, Wuhan (CN)

(21) Appl. No.: 14/584,738

(22) Filed: Dec. 29, 2014

(30) Foreign Application Priority Data
Feb. 28, 2014 (CN) 201410070593.9

(51) Int. Cl. G01K 13/00; G01R 31/40; G01R 19/165; G01R 19/00

(52) U.S. Cl. CPC G01K 13/00; G01R 19/0092; G01R 31/40; G01R 19/165

(57) ABSTRACT

An overheating indicator system for a power supply includes a detecting device, a control device, and an indicating module coupled to the control device. The detecting device is configured to detect a temperature of a power supply to receive a current value. The control device includes a microcontroller coupled to the detecting device. The microcontroller is configured to set a reference value, compare the current value with the reference value, and send a first drive signal to the indicating module after the current value is greater than the reference value, thereby driving the indicating module to indicate the current value is too high.

### CROSS-REFERENCE TO RELATED APPLICATIONS

This application claims priority to Chinese Patent Application No. 201410070593.9 Feb. 28, 2014, the contents of which are incorporated by reference herein.

### FIELD

The subject matter herein generally relates to an overheating indicator system.

### BACKGROUND

An overheating indicator system may be used to indicate a temperature of a power supply.

### BRIEF DESCRIPTION OF THE DRAWINGS

Implementations of the present technology will now be described, by way of example only, with reference to the attached figures.

FIG. 1 is a block diagram of one embodiment of an overheating indicator system.

FIG. 2 is a circuit diagram of the overheating indicator system.

FIG. 3 is a flowchart of one embodiment of the overheating indicator system.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “comprising, but not necessarily limited to”; it specifically indicates open-ended inclusion or membership in the so-described combination, group, series, and the like.

The present disclosure is described in relation to an overheating indicator system to indicate a temperature of a power supply is too high.

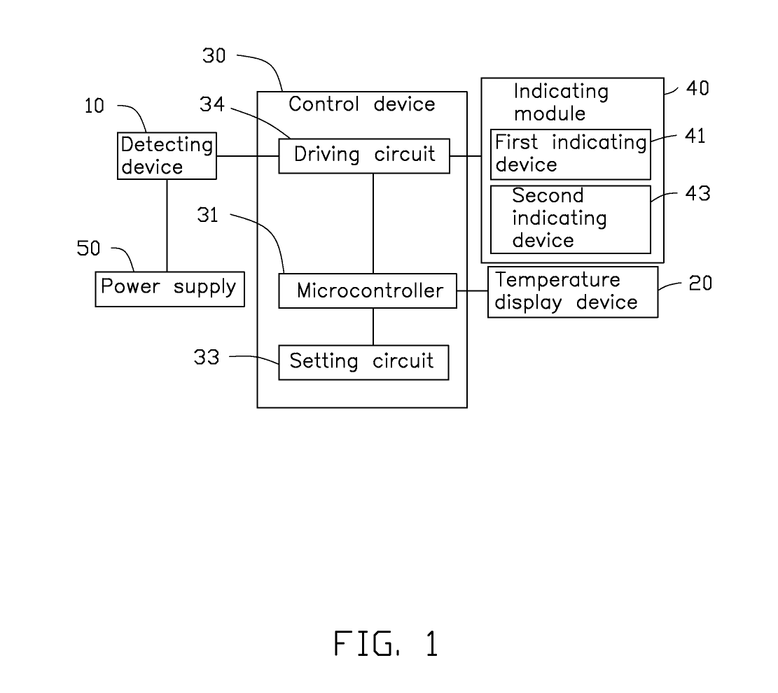

FIG. 1 illustrates one embodiment of an overheating indicator system. The overheating indicator system comprises a detecting device 10, a temperature display device 20, a control device 30 coupled to the detecting device 10, and an indicating module 40 coupled to the control device 30. The temperature display device 20 is coupled to the control device 30. The detecting device 10 is configured to detect the temperature of a power supply 50 to receive a current value. The temperature display device 20 is configured to display the current value of the power supply 50. In one embodiment, the detecting device 10 is a digital thermometer and the power supply 50 is a switching power supply.

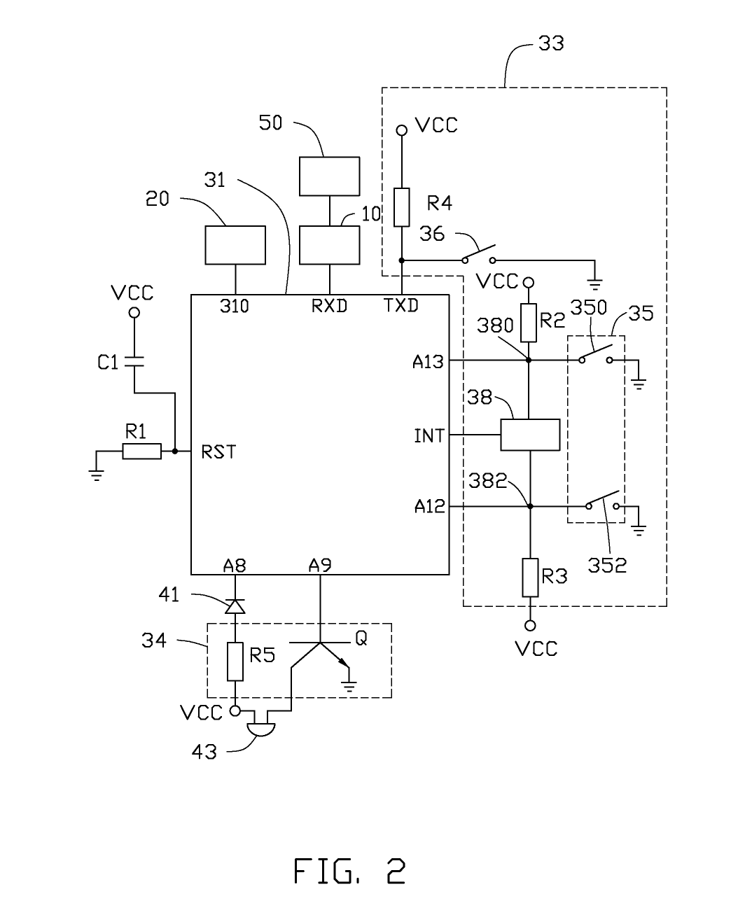

FIG. 2 illustrates that the control device 30 comprises a microcontroller 31, a setting circuit 33, and a driving circuit 34. The setting circuit 33 comprises a switch module 35, a first switch 36, and an AND-circuit 38. The switch module 35 comprises a second switch 350 and a third switch 352. Triggering the switch module 35 can trigger the microcontroller 31 to set a reference value. In one embodiment, a style of the microcontroller 31 is STC851SC. The microcontroller 31 comprises a sending terminal 310, a reset terminal RST, an outer interrupt terminal INT, a data receiving terminal RXD, a data transmit terminal TXD, a first input terminal A12, a second input terminal A13, a first output terminal A8, and a second output terminal A9.

The indicating module 40 comprises a first indicating device 41 and a second indicating device 43. In one embodiment, the first indicating device 41 is a diode and the second indicating device 43 is a buzzer.

The detecting device 10 is coupled to the data receiving terminal RXD. The reset terminal RST is grounded via a first resistor R1 and is coupled to a power supply source VCC via a first capacitor C1. The outer interrupt terminal INT is coupled to an output pin of the AND-circuit 38. One input pin of the AND-circuit 38 is coupled to a first node 380. The first node 380 is coupled to the power supply source VCC via a second resistor R2. The first node 380 is coupled to the second input terminal A13. The first node 380 is grounded via the second switch 350. The other input pin of the AND-circuit 38 is coupled to a second node 382. The second node 382 is coupled to the power supply source VCC via a third resistor R3. The second node 382 is coupled to the first input terminal A12. The second node 382 is grounded via the third switch 352. The data receiving terminal RXD is grounded via the first switch 36 and is coupled to the power supply source VCC via a fourth resistor R4.

In one embodiment, the field effect transistor Q is a triode. The first output terminal A8 is coupled to a cathode of the first indicating device 41. An anode of the first indicating device 41 is coupled to the power supply source VCC via a fifth resistor R5. The second output terminal A9 is coupled to a base of the field effect transistor Q. An emitter of the field effect transistor Q is grounded. A collector of the field effect transistor Q is coupled to second indicating device 43. The second indicating device 43 is coupled to the power supply source VCC.

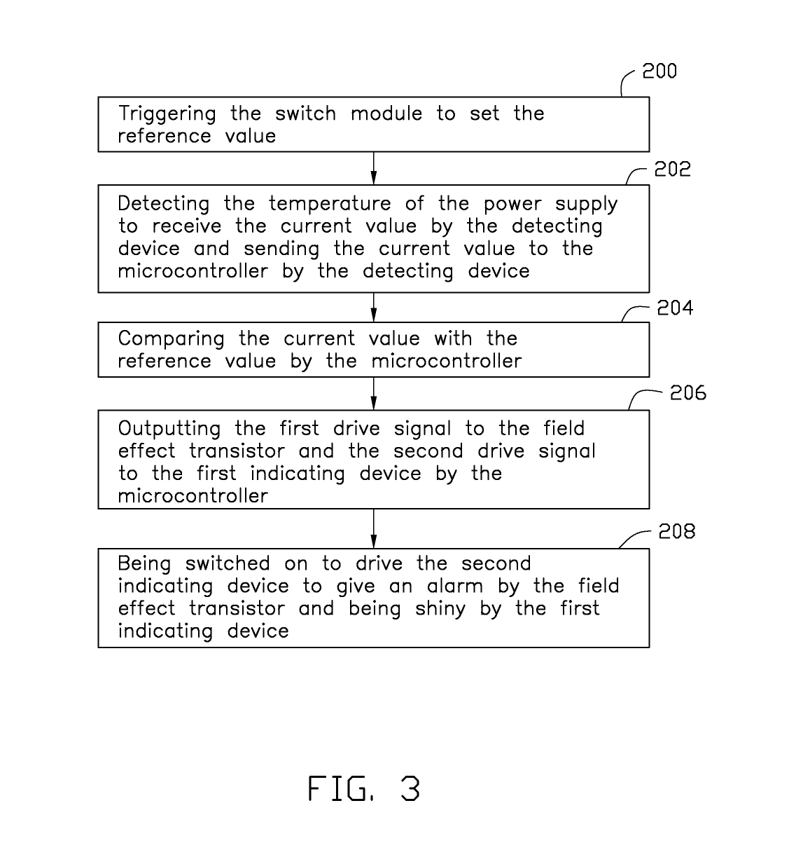

FIG. 3 illustrates a flowchart in accordance with an example embodiment. A method of the overheating indicator system is provided by way of example, as there are a variety of ways to carry out the method. The method of the overheating indicator system described below can be carried out using the configurations illustrated in FIG. 1, for example, and various elements of these figures are referenced in explaining method of the overheating indicator system. In FIG. 3 each block represents one or more processes, methods, or subroutines carried out in the voice-recognition method. Additionally, the illustrated order of blocks is by example only and the order of the blocks can change. The method of the overheating indicator system can begin at block 200. a flow chart of the overheating indicator system. The first switch 36 is switched on. The reference value is set by triggering the switch module 35. The second switch 350 is switched on one time to trigger the microcontroller 31 to control the reference value to be increased 1 degree. The third switch 352 is switched on one time to trigger the microcontroller 31 to control the reference value to be increased 1 degree. The detecting device 10 detects a temperature of the power supply 50 to receive the current value and sends the current value to the microcontroller 31. The microcontroller 31 compares the current value with the reference value. The microcontroller 31 outputs a first drive signal to switch on the field effect transistor Q and outputs a second drive signal to the first indicating device 41 after the current value is greater than the reference value. The first indicating device 41 lights after receiving the second drive signal. The field effect transistor Q is switched on to drive the second indicating device 43 to sound an alarm after receiving the first drive signal. The first indicating device 41 lights and the second indicating device 43 sounds an alarm, thereby indicating the current value is too high.

At block 200, the switch module 35 is triggered to set the reference value.

At block 202, the detecting device 10 detects the temperature of the power supply 50 to receive the current value and sends the current value to the microcontroller 31.

At block 204, the microcontroller 31 compares the current value with the reference value.

At block 206, the microcontroller 31 outputs the first drive signal to the field effect transistor Q and outputs the second drive signal to the first indicating device 41.

At block 208, the first indicating device 41 is switched on to drive the second indicating device 43 to give an alarm by the field effect transistor Q and the first indicating device 41 is shiny.

In the embodiment, the microcontroller 31 outputs the first drive signal to switch on the field effect transistor Q and outputs the second drive signal to the first indicating device 41. The first indicating device 41 lights after receiving the second drive signal. The field effect transistor Q is switched on to drive the second indicating device 43 to sound an alarm after receiving the first drive signal. The first indicating device 41 lights and the second indicating device 43 sounds an alarm, thereby indicating the current value is too high.

It is to be understood that even though numerous characteristics and advantages have been set forth in the foregoing description of embodiments, together with details of the structures and functions of the embodiments, the disclosure is illustrative only and changes may be made in detail, including in the matters of shape, size, and arrangement of parts within the principles of the disclosure to the full extent indicated by the broad general meaning of the terms in which the appended claims are expressed.

What is claimed is:

1. An overheating indicator system comprising:
a power supply;
a detecting device configured to detect a temperature of the power supply and assign a current value corresponding to the detected temperature;
a control device having a microcontroller; and
an indicating module coupled to the control device,
wherein the microcontroller is coupled to the detecting device,
wherein the microcontroller is configured to set a reference value,
wherein the microcontroller is also configured to compare the current value with the reference value, and
wherein the microcontroller is further configured to send a drive signal to the indicating module if current value is greater than the reference value, thereby driving the indicating module to indicate the current value is too high.

2. The overheating indicator system of claim 1, wherein the control device further comprises a setting circuit coupled to the microcontroller, the setting circuit comprises a first switch, the microcontroller comprises an outer interrupt terminal coupled to the first switch, and the microcontroller is being triggered to change the reference value after the first switch is switched on.

3. The overheating indicator system of claim 2, wherein the setting circuit further comprises a second switch coupled to the outer interrupt terminal of the microcontroller, and the microcontroller is being triggered to change the reference value after the second switch is switched on.

4. The overheating indicator system of claim 3, wherein the microcontroller is being triggered to increase the reference value after the first switch is switched on and to decrease the reference value after the second switch is switched on.

5. The overheating indicator system of claim 4, wherein the setting circuit further comprises an AND-circuit, an output pin of the AND-circuit is coupled to the outer interrupt terminal of the microcontroller, and two input pins of the AND-circuit are coupled to the first switch and the second switch, respectively.

6. The overheating indicator system of claim 1, wherein the control device further comprises a driving circuit coupled to the microcontroller, the driving circuit comprises a field effect transistor, the field effect transistor is coupled to the microcontroller and the indicating module, and the field effect transistor is switched on to drive the indicating module to indicate the current value is too high after receiving the drive signal.

7. The overheating indicator system of claim 1, wherein the indicating module comprises a first indicating device coupled to the microcontroller, the first drive signal is configured to drive the first indicating device to indicate the current value is too high.

8. The overheating indicator system of claim 7, wherein the indicating module further comprises a second indicating device coupled to the field effect transistor, the microcontroller is configured to send a second drive signal to switch on the field effect transistor after the current value is greater than the reference value, and the field effect transistor is configured to drive the second indicating device to indicate the current value is too high after being switched on.

9. The overheating indicator system of claim 7, wherein the first indicating device is a diode.

10. The overheating indicator system of claim 1, wherein the detecting device is a digital thermometer.

11. An overheating indicator system comprising:
a power supply;
a detecting device configured to detect a temperature of the power supply and assign a current value corresponding to the detected temperature;
a control device having a microcontroller coupled to the detecting device and a setting circuit coupled to the microcontroller; and
an indicating module coupled to the control device, wherein the microcontroller is coupled to the detecting device;
wherein the microcontroller is configured to set a reference value;
wherein the microcontroller is triggered to change the reference value after the setting circuit is switched on;
wherein the microcontroller is also configured to compare the current value with the reference value, and
wherein the microcontroller is further configured to send a drive signal to the indicating module after the current value is greater than the reference value, thereby driving the indicating module to indicate the current value is too high.

12. The overheating indicator system of claim 11, wherein the setting circuit comprises a first switch, the microcontroller comprises an outer interrupt terminal coupled to the first switch, and the microcontroller is being triggered to change the reference value after the first switch is switched on.

13. The overheating indicator system of claim 12, wherein the setting circuit further comprises a second switch coupled to the outer interrupt terminal of the microcontroller, and the microcontroller is being triggered to change the reference value after the second switch is switched on.

14. The overheating indicator system of claim 13, wherein the microcontroller is being triggered to increase the reference value after the first switch is switched on and to decrease the reference value after the second switch is switched on.

15. The overheating indicator system of claim 14, wherein the setting circuit further comprises an AND-circuit, an output pin of the AND-circuit is coupled to the outer interrupt terminal of the microcontroller, and two input pins of the AND-circuit are coupled to the first switch and the second switch, respectively.

16. The overheating indicator system of claim 11, wherein the control device further comprises a driving circuit coupled to the microcontroller, the driving circuit comprises a field effect transistor, the field effect transistor is coupled to the microcontroller and the indicating module, and the field effect transistor is switched on to drive the indicating module to indicate the current value is too high after receiving the drive signal.

17. The overheating indicator system of claim 16, wherein the field effect transistor is a triode.

18. The overheating indicator system of claim 11, wherein the indicating module comprises a first indicating device coupled to the microcontroller, the first drive signal is configured to drive the first indicating device to indicate the current value is too high.

19. The overheating indicator system of claim 18, wherein the indicating module further comprises a second indicating device coupled to the field effect transistor, the microcontroller is configured to send a second drive signal to switch on the field effect transistor after the current value is greater than the reference value, and the field effect transistor is configured to drive the second indicating device to indicate the current value is too high after being switched on.

20. The overheating indicator system of claim 19, wherein the second indicating device is a buzzer.
